(19) United States
(12) Patent Application Publication
(10) Pub. No.: US 2025/0372575 A1
(43) Pub. Date: Dec. 4, 2025

(54) PROCESS FOR FLIP CHIP PACKAGING

(71) Applicant: ABLEPRINT TECHNOLOGY CO., LTD., Hsinchu (TW)

(72) Inventor: Chih-Horng Horng, Hsinchu (TW)

(21) Appl. No.: 19/213,021

(22) Filed: May 20, 2025

(30) Foreign Application Priority Data
May 31, 2024 (TW) 113120191

(51) Int. Cl. H01L 23/00; H01L 21/56

(52) U.S. Cl. CPC H01L 24/92; H01L 21/563; H01L 24/29; H01L 24/81; H01L 2224/2929; H01L 2224/29298; H01L 2224/81815; H01L 2224/92125

(57) ABSTRACT

A process for flip chip packaging includes: preparing a plurality of chips, each provided with a plurality of conductive bumps; preparing a plurality of circuit substrates, each provided with a solder pad; flipping and aligning each of the chips, conveying each of the chips and each of the circuit substrates into a batch reflow oven, and performing a metal soldering operation to prepare a plurality of flip chip package structures; infilling a liquid material to cover a substance to be cleaned on each of the circuit substrates; placing the flip chip package structures in a processing chamber for heating; and performing intermittent pressurization and depressurization and/or intermittent vacuuming on gas in the processing chamber, and removing the substance to be cleaned from the circuit substrates via frictional scrubbing driven by high energy generated by fluctuation of the liquid material due to a fluctuation change of the gas.

### CROSS REFERENCE TO RELATED APPLICATIONS

The present application claims the benefit of Taiwanese Patent Application No. 113120191 filed on May 31, 2024, the contents of which are incorporated herein by reference in their entirety.

### TECHNICAL FIELD

The present disclosure belongs to the technical field of flip chip package, and in particular, provides a process for flip chip packaging in terms of technology. A batch reflow oven is used to sequentially perform metal soldering operations of heating, melting, and cooling on aligned chips and circuit substrates in large quantities and simultaneously within a specific time, and a liquid material is driven through airflow fluctuation of intermittent pressurization and depressurization to generate a scrubbing or stirring effect, thereby improving the cleaning efficiency of residues, effectively simplifying the process for flip chip packaging, and greatly increasing the production efficiency.

### BACKGROUND

In an era of rapid technological advancement, high-tech electronic technologies are continuously emerging, so that more user-friendly electronic products with better functions are constantly introduced and designed to be lighter, thinner, shorter, and smaller. To meet the above requirements, it is essential to fulfill various demands such as high-speed processing, multifunctionality, integration, miniaturization, lightweight design, and low cost of electronic components. Consequently, integrated circuit package technology is also developing towards miniaturization and higher density. Among various package technologies, flip chip package (F/C package) and other high-density integrated circuit package technologies that utilize bumps or solder balls for electrical connections have gradually become the mainstream in high-density package. This is because they can shorten wiring lengths and thus increase signal transmission speeds.

In a conventional process for flip chip packaging, an adhesive is often required for bonding materials. Especially during metal bonding, some adhesives typically have high acid content and are corrosive, so as to remove a dense oxide layer formed on the bonding surface. However, the corrosive nature of this adhesive seriously affects the performance of microelectronic components. As a result, an additional cleaning step is necessary to remove the adhesive remaining on the bonding surface or reaction residues of the adhesive and metal oxides. Additionally, some adhesives may leave behind certain organic substances after use, resulting in the formation of a layer of grease on the bonding surface, which also requires a cleaning step to avoid reliability issues for semiconductor elements in subsequent processes. However, when circuits on circuit substrates become denser, or bonding protrusions on the circuit substrates become smaller, or gaps between the circuit substrates and solder pads during bonding become narrower, it is increasingly difficult to clean the above residues. If the corrosive adhesive remaining on the circuit substrates or at the bonding positions is not completely removed, the reliability of the components is greatly reduced. In addition, when the above residues are cleaned with a cleaning solvent commonly used at present, improper treatment will have an impact on the environment, so there is indeed a need for improvement.

Therefore, in view of the problems existing in the above conventional process for flip chip packaging, developing a package process with more ideal practicality and economic efficiency is actually the goal and direction that relevant practitioners must strive to achieve through research and development.

In view of this, based on years of experience in the manufacturing, development and design of related products, the inventor, after detailed design and careful evaluation aiming at the above goal, has finally obtained the present disclosure which is truly practical.

### SUMMARY

The technical problems to be solved are as follows: In a conventional process for flip chip packaging, an adhesive is often required for bonding materials. Especially during metal bonding, some adhesives typically have high acid content and are corrosive, so as to remove a dense oxide layer formed on the bonding surface. However, the corrosive nature of this adhesive seriously affects the performance of microelectronic components. As a result, an additional cleaning step is necessary to remove the adhesive remaining on the bonding surface or reaction residues of the adhesive and metal oxides. However, when circuits on circuit substrates become denser, or bonding protrusions on the circuit substrates become smaller, or gaps between the circuit substrates and solder pads during bonding become narrower, it is increasingly difficult to clean the above residues, so there is indeed a need for improvement.

Technical features for solving the problems: To improve the above problems, provided in the present disclosure is a process for flip chip packaging, including the following steps: a: preparing a plurality of chips, where each of the chips is provided with an active surface, a plurality of conductive bumps are disposed on the active surface, and the conductive bump has a component that is selected from at least one of tin, silver, copper, gold, indium, lead, bismuth, zinc, or nickel, or other materials conducive to soldering. b: preparing a plurality of circuit substrates, where each of the circuit substrates is provided with a bearing surface, and a solder pad corresponding to each of the conductive bumps is disposed on the bearing surface;
c: coating a surface of each of the solder pads with a soldering flux, flipping and aligning each of the chips to ensure that the active surface of each of the chips is configured facing the bearing surface of each of the circuit substrates, conveying each of the aligned chips and each of the circuit substrates into a batch reflow oven, bonding each of the conductive bumps to each of the solder pads via the soldering flux, and performing a metal soldering operation to electrically and structurally connect each of the chips to each of the solder pads on each of the circuit substrates by means of each of the conductive bumps, thereby preparing a plurality of flip chip package structures for signal transmission between the circuit substrates and the chips;
d: infilling a liquid material between each of the circuit substrates and each of the chips to cover a substance to be cleaned on each of the circuit substrates;
e: placing each of the flip chip package structures containing the liquid material in a processing chamber, and heating the processing chamber to at least a predetermined temperature, so as to increase the flowability of the liquid material, where the predetermined temperature needs to match the viscosity of the liquid material and is between 25° C. and 200° C.; and
f: performing intermittent vacuuming on gas in the processing chamber by a vacuum generator to generate a wavy airflow, which is a fluctuation under vacuum, performing intermittent fluctuation within a range from a maximum value no greater than 1 atm to a minimum value of 10⁻⁵ atm, and removing the substance to be cleaned that is attached to each of the circuit substrates from each of the circuit substrates and the liquid material more effectively via frictional scrubbing driven by high energy generated by fluctuation of the liquid material in contact with the substance to be cleaned due to a fluctuation change in the liquid material caused by a fluctuation change of a vacuum suction force of the gas, thereby achieving an effect that conventional solution cleaning cannot accomplish.

Provided in the present disclosure is another process for flip chip packaging, including the following steps: a: preparing a plurality of chips, where each of the chips is provided with an active surface, a plurality of conductive bumps are disposed on the active surface, and the conductive bump has a component that is selected from at least one of tin, silver, copper, gold, indium, lead, bismuth, zinc, or nickel, or other materials conducive to soldering. b: preparing a plurality of circuit substrates, where each of the circuit substrates is provided with a bearing surface, and a solder pad corresponding to each of the conductive bumps is disposed on the bearing surface;
c: coating a surface of each of the solder pads with a soldering flux, flipping and aligning each of the chips to ensure that the active surface of each of the chips is configured facing the bearing surface of each of the circuit substrates, conveying each of the aligned chips and each of the circuit substrates into a batch reflow oven, bonding each of the conductive bumps to each of the solder pads via the soldering flux, and performing a metal soldering operation to electrically and structurally connect each of the chips to each of the solder pads on each of the circuit substrates by means of each of the conductive bumps, thereby preparing a plurality of flip chip package structures for signal transmission between the circuit substrates and the chips;
d: infilling a liquid material between each of the circuit substrates and each of the chips to cover a substance to be cleaned on each of the circuit substrates;
e: placing each of the flip chip package structures containing the liquid material in a processing chamber, and heating the processing chamber to at least a predetermined temperature, so as to increase the flowability of the liquid material, where the predetermined temperature needs to match the viscosity of the liquid material and is between 25° C. and 200° C.; and
f: performing intermittent pressurization and depressurization and intermittent vacuuming on gas in the processing chamber by a pressurization and depressurization apparatus and/or a vacuum generator to generate a wavy airflow, which is a fluctuation from a high pressure to vacuum, performing intermittent fluctuation within a range from a maximum value of 50 atm to a minimum value of 10⁻⁵ atm, and removing the substance to be cleaned that is attached to each of the circuit substrates from each of the circuit substrates and the liquid material more effectively via frictional scrubbing driven by high energy generated by fluctuation of the liquid material in contact with the substance to be cleaned due to a fluctuation change in the liquid material caused by a fluctuation change of a vacuum suction force of the gas, thereby achieving an effect that conventional solution cleaning cannot accomplish.

Provided in the present disclosure is yet another process for flip chip packaging, including the following steps: a: preparing a plurality of chips, where each of the chips is provided with an active surface, a plurality of conductive bumps are disposed on the active surface, and the conductive bump has a component that is selected from at least one of tin, silver, copper, gold, indium, lead, bismuth, zinc, or nickel, or other materials conducive to soldering. b: preparing a plurality of circuit substrates, where each of the circuit substrates is provided with a bearing surface, and a solder pad corresponding to each of the conductive bumps is disposed on the bearing surface;
c: coating a surface of each of the solder pads with a soldering flux, flipping and aligning each of the chips to ensure that the active surface of each of the chips is configured facing the bearing surface of each of the circuit substrates, conveying each of the aligned chips and each of the circuit substrates into a batch reflow oven, bonding each of the conductive bumps to each of the solder pads via the soldering flux, and performing a metal soldering operation to electrically and structurally connect each of the chips to each of the solder pads on each of the circuit substrates by means of each of the conductive bumps, thereby preparing a plurality of flip chip package structures for signal transmission between the circuit substrates and the chips;
d: infilling a liquid material between each of the circuit substrates and each of the chips to cover a substance to be cleaned on each of the circuit substrates;
e: placing each of the flip chip package structures containing the liquid material in a processing chamber, and heating the processing chamber to at least a predetermined temperature, so as to increase the flowability of the liquid material, where the predetermined temperature needs to match the viscosity of the liquid material and is between 25° C. and 200° C.; and
f: performing intermittent pressurization and depressurization on gas in the processing chamber by a pressurization and depressurization apparatus to generate a wavy airflow, which is a fluctuation from high pressure to 1 atm, performing intermittent fluctuation within a range from a maximum value of 50 atm to a minimum value of 1 atm, and removing the substance to be cleaned that is attached to each of the circuit substrates from each of the circuit substrates and the liquid material more effectively via frictional scrubbing driven by high energy generated by fluctuation of the liquid material in contact with the substance to be cleaned due to a fluctuation change in the liquid material caused by a fluctuation change of a vacuum suction force of the gas, thereby achieving an effect that conventional solution cleaning cannot accomplish.

Further provided in the present disclosure is a process for flip chip packaging, including the following steps: a: preparing a plurality of chips, where each of the chips is provided with an active surface, a plurality of conductive bumps are disposed on the active surface, and the conductive bump has a component that is selected from at least one of tin, silver, copper, gold, indium, lead, bismuth, zinc, or nickel, or other materials conducive to soldering. b: preparing a plurality of circuit substrates, where each of the circuit substrates is provided with a bearing surface, and a solder pad corresponding to each of the conductive bumps is disposed on the bearing surface;
c: coating a surface of each of the solder pads with a soldering flux, flipping and aligning each of the chips to ensure that the active surface of each of the chips is configured facing the bearing surface of each of the circuit substrates, conveying each of the aligned chips and each of the circuit substrates into a batch reflow oven, bonding each of the conductive bumps to each of the solder pads via the soldering flux, and performing a metal soldering operation to electrically and structurally connect each of the chips to each of the solder pads on each of the circuit substrates by means of each of the conductive bumps, thereby preparing a plurality of flip chip package structures for signal transmission between the circuit substrates and the chips;
d: infilling a liquid material between each of the circuit substrates and each of the chips to cover a substance to be cleaned on each of the circuit substrates;
e: placing each of the flip chip package structures containing the liquid material in a processing chamber, and heating the processing chamber to at least a predetermined temperature, so as to increase the flowability of the liquid material, where the predetermined temperature needs to match the viscosity of the liquid material and is between 25° C. and 200° C.; and
f: generating at least a predetermined stable gas pressure greater than 1 atm and ranging from a maximum value of 50 atm to a minimum value of 1 atm in the processing chamber by a pressurization apparatus, dissolving the substance to be cleaned that is attached to each of the circuit substrates in the liquid material by using physical dissolution caused by contact between the infilled liquid material and the substance to be cleaned, and diffusing the substance to be cleaned in the liquid material by using a diffusion force generated by the predetermined temperature and a concentration gradient after dissolution to remove the substance to be cleaned from each of the circuit substrates and the liquid material, thereby achieving an effect that conventional solution cleaning cannot accomplish.

As described above, the circuit substrate is at least one of a printed circuit board, an organic substrate, a glass substrate, a metal substrate, a lead frame, a wafer, a silicon interposer, or a package.

As described above, a surface of each of the solder pads is coated with a soldering flux by means of spraying, dipping, or painting.

As described above, the soldering flux is a liquid soldering flux with the viscosity ranging from 1 centipoises (cps) to 1,000 pascal second (Pa·s).

As described above, the substance to be cleaned is the soldering flux, a soldering flux residue, grease, a photoresist, or a substance generated in the process.

As described above, the liquid material is an underfill, the underfill is capable of containing hard particles, the hard particles roll as the underfill fluctuates, and a frictional scrubbing effect is enhanced by means of the hard particles to assist in cleaning the substance to be cleaned.

As described above, the underfill has a component of epoxy resin doped with a filler such as SiO₂ powder.

As described above, each of the aligned chips and each of the circuit substrates are conveyed into the batch reflow oven manually or by means of an automated conveying device.

As described above, each of the aligned chips and each of the circuit substrates are conveyed manually.

As described above, the automated conveying device includes at least one transfer vehicle and at least one magazine, where each of the aligned chips and each of the circuit substrates are accommodated in the at least one magazine, and the at least one transfer vehicle conveys each of the aligned chips and each of the circuit substrates.

As described above, the transfer vehicle includes an overhead hoist transport (OHT), an automated guided vehicle (AGV), an autonomous mobile robot (AMR), and a rail guided vehicle (RGV).

Compared with the prior art, the present disclosure has the following effects: In the process for flip chip packaging of the present disclosure, a batch reflow oven is used to sequentially perform metal soldering operations of heating, melting, and cooling on the aligned chips and the circuit substrates in large quantities and simultaneously for a long time, and the liquid material fluctuates by controlling the fluctuation of the gas in the processing chamber to generate a cleaning effect of wave-like frictional scrubbing, or dissolution of the substance to be cleaned in the liquid material is accelerated, which is similar to adding sugar to water and stirring to accelerate dissolution of the sugar, so that the substance to be cleaned that is attached to the circuit substrates can be removed from the circuit substrate via the frictional scrubbing driven by high energy generated by fluctuation of the liquid material in contact with the substance to be cleaned due to the fluctuation, thereby improving the cleaning efficiency of residues, effectively simplifying the process for flip chip packaging, and greatly increasing the production efficiency; or gas with at least a predetermined pressure is provided to dissolve the substance to be cleaned in the liquid material, and the substance to be cleaned is removed from the circuit substrate by utilizing a diffusion principle; in addition, when the temperature in the processing chamber is increased to a value between 25° C. and 200° C. by heating, grease, some substances to be cleaned, or water vapor adsorbed inside the circuit substrates will volatilize and generate gases due to heating, where based on the fluctuation under vacuum, the fluctuation from the high pressure to 1 atm, or the fluctuation from the high pressure to vacuum, these gases can be discharged out of the liquid material by fluctuating the liquid material via the gas fluctuation or by accelerating the dissolution and diffusion between materials in a high-pressure environment.

Regarding the technologies and means adopted by the present disclosure and the effects thereof, multiple preferred embodiments are hereby cited and will be described in detail below with reference to the drawings. It is believed that the above objectives, structures and features of the present disclosure can be deeply and specifically understood thereby.

### BRIEF DESCRIPTION OF THE DRAWINGS

FIG. 1 is a flowchart of a process for flip chip packaging in an embodiment of the present disclosure;

FIG. 2 is a flowchart of a process for flip chip packaging in another embodiment of the present disclosure;

FIG. 3 is a flowchart of a process for flip chip packaging in yet embodiment of the present disclosure;

FIG. 4 is a flowchart of a process for flip chip packaging in a further embodiment of the present disclosure; and

FIGS. 5A to 5E are schematic sectional views of the process for flip chip packaging in FIGS. 1 to 4.

In the above, taking the schematic sectional view of a single flip chip package structure process as an example, the schematic sectional views of a plurality of flip chip package structure processes can be deduced by analogy.

### DETAILED DESCRIPTION OF THE EMBODIMENTS

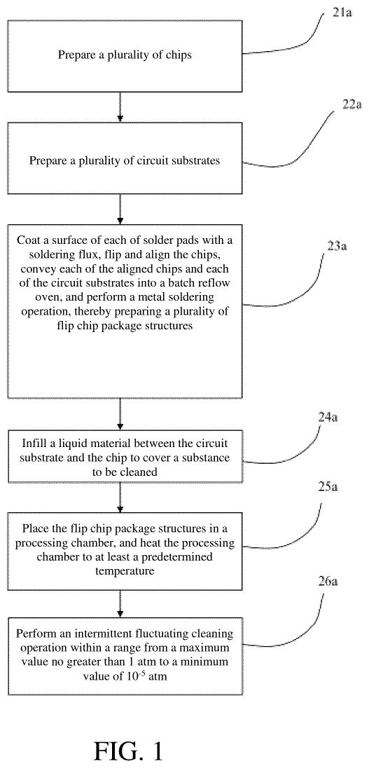

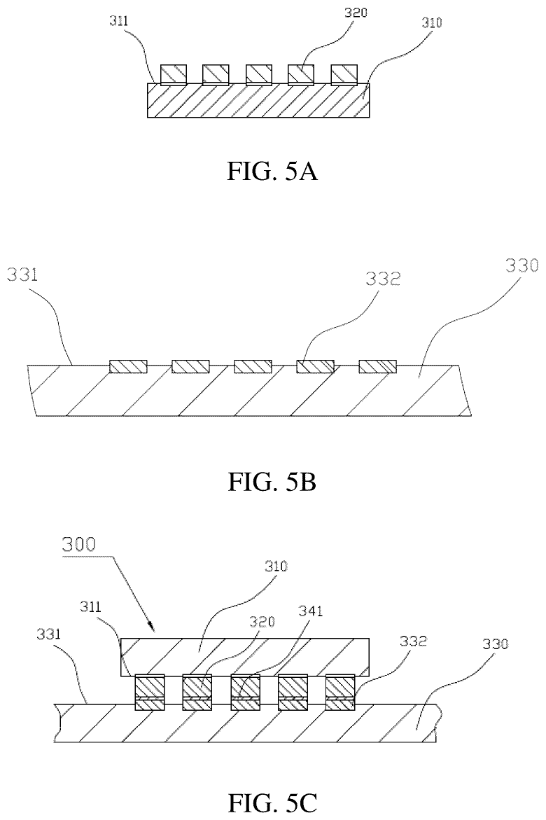

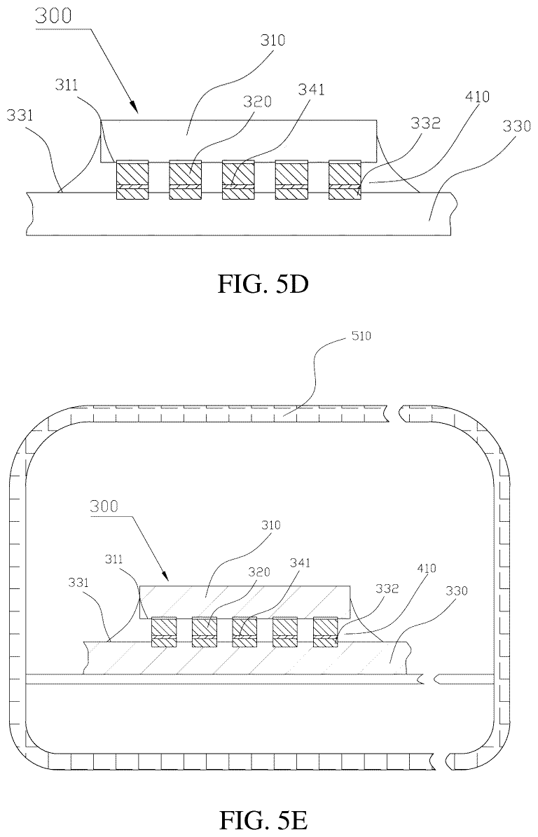

Reference is made to FIG. 1 and FIG. 5A to FIG. 5E, where FIG. 1 is a flowchart of a process for flip chip packaging in an embodiment of the present disclosure, and FIGS. 5A to 5E are schematic sectional views of this process for flip chip packaging. Provided in the present disclosure is a process for flip chip packaging, including the following steps: a (step 21a): preparing a plurality of chips 310, where each of the chips 310 is provided with an active surface 311, a plurality of conductive bumps 320 are disposed on the active surface 311 (as shown in FIG. 5A), and the conductive bumps 320 are solder bumps prepared by means of a general bumping process and have a component that is selected from at least one of tin, silver, copper, gold, indium, lead, bismuth, zinc, or nickel, or other materials conducive to soldering;
b (step 22a): preparing a plurality of circuit substrates 330, where each of the circuit substrates 330 is provided with a bearing surface 331, and a solder pad 332 corresponding to each of the conductive bumps 320 is disposed on the bearing surface 331 (as shown in FIG. 5B);
c (step 23a): coating a surface of each of the solder pads 332 with a soldering flux, flipping and aligning each of the chips 310 to ensure that the active surface 311 of each of the chips 310 is configured facing the bearing surface 331 of each of the circuit substrates 330, conveying each of the aligned chips and each of the circuit substrates into a batch reflow oven, bonding each of the conductive bumps 320 to each of the solder pads 332 via the soldering flux (as shown in FIG. 5C), and performing a metal soldering operation to electrically and structurally connect each of the chips 310 to each of the solder pads 332 on each of the circuit substrates 330 by means of each of the conductive bumps 320, thereby preparing a plurality of flip chip package structures 300 for signal transmission between the circuit substrates 330 and the chips 310, where the metal soldering operation performed herein refers to a metal soldering operation performed on the aligned chip 310 and the circuit substrate 330, and each of the conductive bumps 320 and each of the solder pads 332, so that each of the conductive bumps 320 in a heated molten or semi-molten state is bonded to each of the solder pads 332 on the bearing surface 331 of each of the circuit substrates 330;
d (step 24a): infilling a liquid material 410 between each of the circuit substrates 330 and each of the chips 310 to cover a substance to be cleaned on each of the circuit substrates (as shown in FIG. 5D);
e (step 25a): placing each of the flip chip package structures 300 containing the liquid material 410 in a processing chamber 510 (as shown in FIG. 5E), and heating the processing chamber 510 to at least a predetermined temperature, so as to increase the flowability of the liquid material, where the predetermined temperature needs to match the viscosity of the liquid material and is between 25° C. and 200° C.; and
f (step 26a): performing intermittent vacuuming on gas in the processing chamber 510 by a vacuum generator (not shown in figure) to generate a wavy airflow, which is a fluctuation under vacuum, performing intermittent fluctuation within a range from a maximum value no greater than 1 atm to a minimum value of 10⁻⁵ atm, and removing the substance to be cleaned that is attached to each of the circuit substrates 330 from each of the circuit substrates 330 and the liquid material 410 more effectively via frictional scrubbing of high energy generated by fluctuation of the liquid material 410 in contact with the substance to be cleaned due to a fluctuation change in the liquid material 410 caused by a fluctuation change of a vacuum suction force of the gas, thereby achieving an effect that conventional solution cleaning cannot accomplish, where the liquid material 410 exists between each of the chips 310 and each of the circuit substrates 330, and due to a capillary force between them and a surface tension of the liquid material 410, the liquid material 410 can be pulled to generate a great fluctuation without overflowing; and as the liquid material 410 is pulled to generate a fluctuation through the fluctuation of the gas, direct transfer of energy can be reduced, and damage to an object or splashing of the liquid material 410 due to excessive fluctuation can be alleviated.

As described above, the viscosity of the liquid soldering flux ranges from 1 centipoises (cps) to 1,000 pascal second (Pas).

As described above, the substance to be cleaned is the soldering flux, a soldering flux residue, grease, a photoresist, or a substance generated in the process.

As described above, the liquid material 410 is an underfill, the underfill is capable of containing hard particles, the hard particles roll as the underfill fluctuates, and a frictional scrubbing effect is enhanced by means of the hard particles to assist in cleaning the substance to be cleaned.

As described above, the underfill has a component of epoxy resin doped with a filler such as SiO₂ powder.

As described above, each of the aligned chips 310 and each of the circuit substrates 330 are conveyed manually or by means of an automated conveying device.

As described above, each of the aligned chips 310 and each of the circuit substrates 330 are conveyed manually.

As described above, the automated conveying device includes at least one transfer vehicle and at least one magazine, where each of the aligned chips 310 and each of the circuit substrates 330 are accommodated in the at least one magazine, and the at least one transfer vehicle conveys each of the aligned chips 310 and each of the circuit substrates 330.

As described above, the transfer vehicle includes an overhead hoist transport (OHT), an automated guided vehicle (AGV), an autonomous mobile robot (AMR), and a rail guided vehicle (RGV).

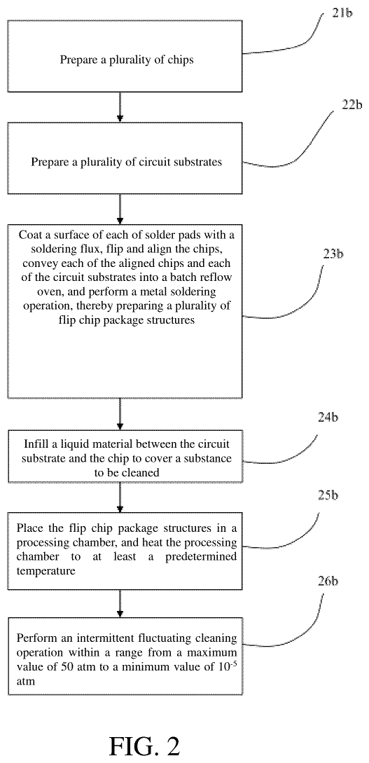

Reference is made to FIG. 2 and FIG. 5A to FIG. 5E, where FIG. 2 is a flowchart of a process for flip chip packaging in another embodiment of the present disclosure, and FIGS. 5A to 5E are schematic sectional views of this process for flip chip packaging. Provided in the present disclosure is a process for flip chip packaging, including the following steps: a (step 21b): preparing a plurality of chips 310, where each of the chips 310 is provided with an active surface 311, a plurality of conductive bumps 320 are disposed on the active surface 311 (as shown in FIG. 5A), and the conductive bumps 320 are solder bumps prepared by means of a general bumping process and have a component that is selected from at least one of tin, silver, copper, gold, indium, lead, bismuth, zinc, or nickel, or other materials conducive to soldering;
b (step 22b): preparing a plurality of circuit substrates 330, where each of the circuit substrates 330 is provided with a bearing surface 331, and a solder pad 332 corresponding to each of the conductive bumps 320 is disposed on the bearing surface 331 (as shown in FIG. 5B);
c (step 23b): coating a surface of each of the solder pads 332 with a soldering flux, flipping and aligning each of the chips 310 to ensure that the active surface 311 of each of the chips 310 is configured facing the bearing surface 331 of each of the circuit substrates 330, conveying each of the aligned chips and each of the circuit substrates into a batch reflow oven, bonding each of the conductive bumps 320 to each of the solder pads 332 via the soldering flux (as shown in FIG. 5C), and performing a metal soldering operation to electrically and structurally connect each of the chips 310 to each of the solder pads 332 on each of the circuit substrates 330 by means of each of the conductive bumps 320, thereby preparing a plurality of flip chip package structures 300 for signal transmission between the circuit substrates 330 and the chips 310, where the metal soldering operation performed herein refers to a metal soldering operation performed on the aligned chip 310 and the circuit substrate 330, and each of the conductive bumps 320 and each of the solder pads 332, so that each of the conductive bumps 320 in a heated molten or semi-molten state is bonded to each of the solder pads 332 on the bearing surface 331 of each of the circuit substrates 330;
d (step 24b): infilling a liquid material 410 between each of the circuit substrates 330 and each of the chips 310 to cover a substance to be cleaned on each of the circuit substrates (as shown in FIG. 5D);
e (step 25b): placing each of the flip chip package structures 300 containing the liquid material 410 in a processing chamber 510 (as shown in FIG. 5E), and heating the processing chamber 510 to a predetermined temperature, so as to increase the flowability of the liquid material, where the predetermined temperature needs to match the viscosity of the liquid material and is between 25° C. and 200° C.; and
f (step 26b): performing intermittent pressurization and depressurization and intermittent vacuuming on gas in the processing chamber 510 by a pressurization and depressurization apparatus (not shown in figure) and/or a vacuum generator (not shown in figure) to generate a wavy airflow, which is a fluctuation from a high pressure to vacuum, performing intermittent fluctuation within a range from a maximum value of 50 atm to a minimum value of 10⁻⁵ atm, and removing the substance to be cleaned that is attached to each of the circuit substrates 330 from each of the circuit substrates 330 and the liquid material 410 more effectively via frictional scrubbing of high energy generated by fluctuation of the liquid material 410 in contact with the substance to be cleaned due to a fluctuation change in the liquid material 410 caused by a fluctuation change of the gas, thereby achieving an effect that conventional solution cleaning cannot accomplish, where the liquid material 410 exists between the chips 310 and the circuit substrates 330, and due to a capillary force between them and a surface tension of the liquid material 410, the liquid material 410 can be pulled to generate a great fluctuation without overflowing; and as the liquid material 410 is pulled to generate a fluctuation through the fluctuation of the gas, direct transfer of energy can be reduced, and damage to an object or splashing of the liquid material 410 due to excessive fluctuation can be alleviated.

As described above, the viscosity of the liquid soldering flux ranges from 1 cps to 1,000 Pa·s.

As described above, the substance to be cleaned is the soldering flux, a soldering flux residue, grease, a photoresist, or a substance generated in the process.

As described above, the liquid material 410 is an underfill, the underfill is capable of containing hard particles, the hard particles roll as the underfill fluctuates, and a frictional scrubbing effect is enhanced by means of the hard particles to assist in cleaning the substance to be cleaned.

As described above, the underfill has a component of epoxy resin doped with a filler such as SiO₂ powder.

As described above, each of the aligned chips 310 and each of the circuit substrates 330 are conveyed manually or by means of an automated conveying device.

As described above, each of the aligned chips 310 and each of the circuit substrates 330 are conveyed manually.

As described above, the automated conveying device includes at least one transfer vehicle and at least one magazine, where each of the aligned chips 310 and each of the circuit substrates 330 are accommodated in the at least one magazine, and the at least one transfer vehicle conveys each of the aligned chips 310 and each of the circuit substrates 330.

As described above, the transfer vehicle includes an overhead hoist transport (OHT), an automated guided vehicle (AGV), an autonomous mobile robot (AMR), and a rail guided vehicle (RGV).

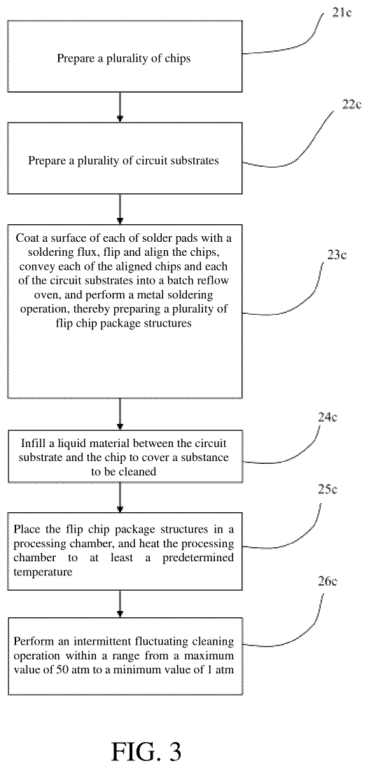

Reference is made to FIG. 3 and FIG. 5A to FIG. 5E, where FIG. 3 is a flowchart of a process for flip chip packaging in yet another embodiment of the present disclosure, and FIGS. 5A to 5E are schematic sectional views of this process for flip chip packaging. Provided in the present disclosure is a process for flip chip packaging, including the following steps: a (step 21c): preparing a plurality of chips 310, where each of the chips 310 is provided with an active surface 311, a plurality of conductive bumps 320 are disposed on the active surface 311 (as shown in FIG. 5A), and the conductive bumps 320 are solder bumps prepared by means of a general bumping process and have a component that is selected from at least one of tin, silver, copper, gold, indium, lead, bismuth, zinc, or nickel, or other materials conducive to soldering;
b (step 22c): preparing a plurality of circuit substrates 330, where each of the circuit substrates 330 is provided with a bearing surface 331, and a solder pad 332 corresponding to each of the conductive bumps 320 is disposed on the bearing surface 331 (as shown in FIG. 5B);
c (step 23c): coating a surface of each of the solder pads 332 with a soldering flux, flipping and aligning each of the chips 310 to ensure that the active surface 311 of each of the chips 310 is configured facing the bearing surface 331 of each of the circuit substrates 330, conveying each of the aligned chips and each of the circuit substrates into a batch reflow oven, bonding each of the conductive bumps 320 to each of the solder pads 332 via the soldering flux (as shown in FIG. 5C), and performing a metal soldering operation to electrically and structurally connect each of the chips 310 to each of the solder pads 332 on each of the circuit substrates 330 by means of each of the conductive bumps 320, thereby preparing a plurality of flip chip package structures 300 for signal transmission between the circuit substrates 330 and the chips 310, where the metal soldering operation performed herein refers to a metal soldering operation performed on the aligned chip 310 and the circuit substrate 330, and each of the conductive bumps 320 and each of the solder pads 332, so that each of the conductive bumps 320 in a heated molten or semi-molten state is bonded to each of the solder pads 332 on the bearing surface 331 of each of the circuit substrates 330;
d (step 24c): infilling a liquid material 410 between each of the circuit substrates 330 and each of the chips 310 to cover a substance to be cleaned on each of the circuit substrates (as shown in FIG. 5D);
e (step 25c): placing each of the flip chip package structures 300 containing the liquid material 410 in a processing chamber 510 (as shown in FIG. 5E), and heating the processing chamber 510 to a predetermined temperature, so as to increase the flowability of the liquid material, where the predetermined temperature needs to match the viscosity of the liquid material and is between 25° C. and 200° C.; and
f (step 26c): performing intermittent pressurization and depressurization on gas in the processing chamber 510 by a pressurization and depressurization apparatus (not shown in figure) to generate a wavy airflow, which is a fluctuation from a high pressure to 1 atm, performing intermittent fluctuation within a range from a maximum value of 50 atm to a minimum value of 1 atm, and removing the substance to be cleaned that is attached to each of the circuit substrates 330 from each of the circuit substrates 330 and the liquid material 410 more effectively via frictional scrubbing of high energy generated by fluctuation of the liquid material 410 in contact with the substance to be cleaned due to a fluctuation change in the liquid material 410 caused by a fluctuation change of the gas, thereby achieving an effect that conventional solution cleaning cannot accomplish, where the liquid material 410 exists between the chips 310 and the circuit substrates 330, and due to a capillary force between them and a surface tension of the liquid material 410, the liquid material 410 can be pulled to generate a great fluctuation without overflowing; and as the liquid material is pulled to generate a fluctuation through the fluctuation of the gas, direct transfer of energy can be reduced, and damage to an object or splashing of the liquid material 410 due to excessive fluctuation can be alleviated.

As described above, the viscosity of the liquid soldering flux ranges from 1 cps to 1,000 Pa·s.

As described above, the substance to be cleaned is the soldering flux, a soldering flux residue, grease, a photoresist, or a substance generated in the process.

As described above, the liquid material 410 is an underfill, the underfill is capable of containing hard particles, the hard particles roll as the underfill fluctuates, and a frictional scrubbing effect is enhanced by means of the hard particles to assist in cleaning the substance to be cleaned.

As described above, the underfill has a component of epoxy resin doped with a filler such as SiO₂ powder.

As described above, each of the aligned chips 310 and each of the circuit substrates 330 are conveyed manually or by means of an automated conveying device.

As described above, each of the aligned chips 310 and each of the circuit substrates 330 are conveyed manually.

As described above, the automated conveying device includes at least one transfer vehicle and at least one magazine, where each of the aligned chips 310 and each of the circuit substrates 330 are accommodated in the at least one magazine, and the at least one transfer vehicle conveys each of the aligned chips 310 and each of the circuit substrates 330.

As described above, the transfer vehicle includes an overhead hoist transport (OHT), an automated guided vehicle (AGV), an autonomous mobile robot (AMR), and a rail guided vehicle (RGV).

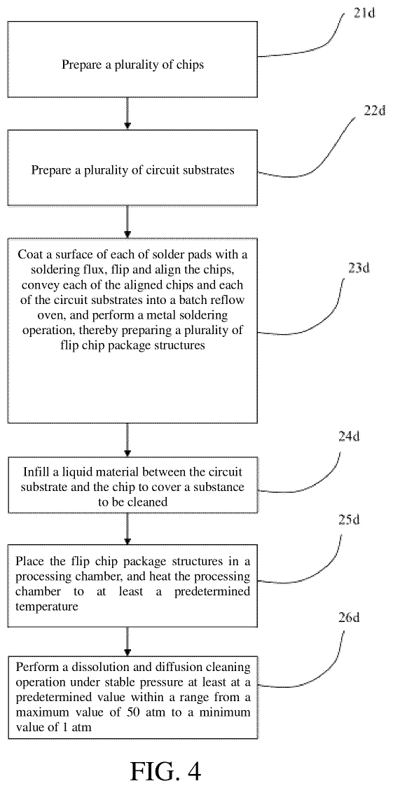

Reference is made to FIG. 4 and FIG. 5A to FIG. 5E, where FIG. 4 is a flowchart of a process for flip chip packaging in a further embodiment of the present disclosure, and FIGS. 5A to 5E are schematic sectional views of this process for flip chip packaging. Provided in the present disclosure is a process for flip chip packaging, including the following steps: a (step 21d): preparing a plurality of chips 310, where each of the chips 310 is provided with an active surface 311, a plurality of conductive bumps 320 are disposed on the active surface 311 (as shown in FIG. 5A), and the conductive bumps 320 are solder bumps prepared by means of a general bumping process and have a component that is selected from at least one of tin, silver, copper, gold, indium, lead, bismuth, zinc, or nickel, or other materials conducive to soldering;
b (step 22d): preparing a plurality of circuit substrates 330, where each of the circuit substrates 330 is provided with a bearing surface 331, and a solder pad 332 corresponding to each of the conductive bumps 320 is disposed on the bearing surface 331 (as shown in FIG. 5B);
c (step 23d): coating a surface of each of the solder pads 332 with a soldering flux, flipping and aligning each of the chips 310 to ensure that the active surface 311 of each of the chips 310 is configured facing the bearing surface 331 of each of the circuit substrates 330, conveying each of the aligned chips and each of the circuit substrates into a batch reflow oven, bonding each of the conductive bumps 320 to each of the solder pads 332 via the soldering flux (as shown in FIG. 5C), and performing a metal soldering operation to electrically and structurally connect each of the chips 310 to each of the solder pads 332 on each of the circuit substrates 330 by means of each of the conductive bumps 320, thereby preparing a plurality of flip chip package structures 300 for signal transmission between the circuit substrates 330 and the chips 310, where the metal soldering operation performed herein refers to a metal soldering operation performed on the aligned chip 310 and the circuit substrate 330, and each of the conductive bumps 320 and each of the solder pads 332, so that each of the conductive bumps 320 in a heated molten or semi-molten state is bonded to each of the solder pads 332 on the bearing surface 331 of each of the circuit substrates 330;
d (step 24d): infilling a liquid material 410 between each of the circuit substrates 330 and each of the chips 310 to cover a substance to be cleaned on each of the circuit substrates (as shown in FIG. 5D);
e (step 25d): placing each of the flip chip package structures 300 containing the liquid material 410 in a processing chamber 510 (as shown in FIG. 5E), and heating the processing chamber 510 to a predetermined temperature, so as to increase the flowability of the liquid material, where the predetermined temperature needs to match the viscosity of the liquid material and is between 25° C. and 200° C.; and
f (step 26d): generating at least a predetermined gas pressure ranging from a maximum value of 50 atm to a minimum value of 1 atm in the processing chamber 510 by a pressurization apparatus (not shown in figure), dissolving the substance to be cleaned that is attached to each of the circuit substrates 330 in the liquid material 410 by using physical dissolution caused by contact between the infilled liquid material 410 and the substance to be cleaned, and removing the substance to be cleaned that is attached to each of the circuit substrates 330 from each of the circuit substrates 330 and the liquid material 410 by using a diffusion force generated by the predetermined temperature and a concentration gradient after dissolution, thereby achieving an effect that conventional solution cleaning cannot accomplish.

As described above, the viscosity of the liquid soldering flux ranges from 1 cps to 1,000 Pa·s.

As described above, the substance to be cleaned is the soldering flux, a soldering flux residue, grease, a photoresist, or a substance generated in the process.

As described above, the liquid material 410 is an underfill, the underfill is capable of containing hard particles, the hard particles roll as the underfill fluctuates, and a frictional scrubbing effect is enhanced by means of the hard particles to assist in cleaning the substance to be cleaned.

As described above, the underfill has a component of epoxy resin doped with a filler such as SiO₂ powder.

As described above, each of the aligned chips 310 and each of the circuit substrates 330 are conveyed manually or by means of an automated conveying device.

As described above, each of the aligned chips 310 and each of the circuit substrates 330 are conveyed manually.

As described above, the automated conveying device includes at least one transfer vehicle and at least one magazine, where each of the aligned chips 310 and each of the circuit substrates 330 are accommodated in the at least one magazine, and the at least one transfer vehicle conveys each of the aligned chips 310 and each of the circuit substrates 330.

As described above, the transfer vehicle includes an overhead hoist transport (OHT), an automated guided vehicle (AGV), an autonomous mobile robot (AMR), and a rail guided vehicle (RGV).

The foregoing provides a detailed description of the technical features of the present disclosure with respect to the preferred embodiments of the present disclosure. However, those skilled in the art can make changes and modifications to the present disclosure without departing from the spirit and principle of the present disclosure, and such changes and modifications shall all be covered within the scope defined by the following claims.

### DESCRIPTION OF REFERENCE SIGNS

21a-26a steps
21b-26b steps
21c-26c steps
21d-26d steps
300 flip chip package structure
310 chip
311 active surface
320 conductive bump
330 circuit substrate
331 bearing surface
332 solder pad
410 liquid material
510 processing chamber:

What is claimed is:

1. A process for flip chip packaging, comprising the following steps:
(a): preparing a plurality of chips, wherein each of the chips is provided with an active surface, and a plurality of conductive bumps are disposed on the active surface;
(b): preparing a plurality of circuit substrates, wherein each of the circuit substrates is provided with a bearing surface, and a solder pad corresponding to each of the conductive bumps is disposed on the bearing surface;
(c): coating a surface of each of the solder pads with a soldering flux, flipping and aligning each of the chips to ensure that the active surface of each of the chips is configured facing the bearing surface of each of the circuit substrates, conveying each of the aligned chips and each of the circuit substrates into a batch reflow oven, bonding each of the conductive bumps to each of the solder pads via the soldering flux, and performing a metal soldering operation to electrically and structurally connect each of the chips to each of the solder pads on each of the circuit substrates by means of each of the conductive bumps, thereby preparing a plurality of flip chip package structures;
(d): infilling a liquid material between each of the circuit substrates and each of the chips to cover a substance to be cleaned on each of the circuit substrates;
(e): placing each of the flip chip package structures containing the liquid material in a processing chamber, and heating the processing chamber to at least a predetermined temperature, wherein the predetermined temperature needs to match the viscosity of the liquid material and is between 25° C. and 200° C.; and
(f): performing intermittent vacuuming on gas in the processing chamber by a vacuum generator to generate a wavy airflow, which is a fluctuation under vacuum, performing intermittent fluctuation within a range from a maximum value no greater than 1 atm to a minimum value of 10⁻⁵ atm, and removing the substance to be cleaned that is attached to each of the circuit substrates from each of the circuit substrates and the liquid material more effectively via frictional scrubbing of the liquid material in contact with the substance to be cleaned due to a fluctuation change in the liquid material caused by a fluctuation change of a vacuum suction force of the gas.

2. The process for flip chip packaging according to claim 1, wherein the soldering flux is a liquid soldering flux with the viscosity ranging from 1 cps to 1,000 Pa·s.

3. The process for flip chip packaging according to claim 1, wherein the substance to be cleaned is the soldering flux, a soldering flux residue, grease, a photoresist, or a substance generated in the process.

4. The process for flip chip packaging according to claim 1, wherein the liquid material is an underfill, the underfill is capable of containing hard particles, the hard particles roll as the underfill fluctuates, and a frictional scrubbing effect is enhanced by means of the hard particles.

5. The process for flip chip packaging according to claim 4, wherein the underfill has a component of epoxy resin.

6. The process for flip chip packaging according to claim 1, wherein each of the aligned chips and each of the circuit substrates are conveyed by means of an automated conveying device.

7. The process for flip chip packaging according to claim 6, wherein the automated conveying device comprises at least one transfer vehicle and at least one magazine, each of the aligned chips and each of the circuit substrates are accommodated in the at least one magazine, and the at least one transfer vehicle conveys each of the aligned chips and each of the circuit substrates.

8. The process for flip chip packaging according to claim 7, wherein the transfer vehicle comprises an overhead hoist transport (OHT), an automated guided vehicle (AGV), an autonomous mobile robot (AMR), and a rail guided vehicle (RGV).

9. A process for flip chip packaging, comprising the following steps:
(a): preparing a plurality of chips, wherein each of the chips is provided with an active surface, and a plurality of conductive bumps are disposed on the active surface;
(b): preparing a plurality of circuit substrates, wherein each of the circuit substrates is provided with a bearing surface, and a solder pad corresponding to each of the conductive bumps is disposed on the bearing surface;
(c): coating a surface of each of the solder pads with a soldering flux, flipping and aligning each of the chips to ensure that the active surface of each of the chips is configured facing the bearing surface of each of the circuit substrates, conveying each of the aligned chips and each of the circuit substrates into a batch reflow oven, bonding each of the conductive bumps to each of the solder pads via the soldering flux, and performing a metal soldering operation to electrically and structurally connect each of the chips to each of the solder pads on each of the circuit substrates by means of each of the conductive bumps, thereby preparing a plurality of flip chip package structures;
(d): infilling a liquid material between each of the circuit substrates and each of the chips to cover a substance to be cleaned on each of the circuit substrates;
(e): placing each of the flip chip package structures containing the liquid material in a processing chamber, and heating the processing chamber to at least a predetermined temperature, wherein the predetermined temperature needs to match the viscosity of the liquid material and is between 25° C. and 200° C.; and
(f): performing intermittent pressurization and depressurization and intermittent vacuuming on gas in the processing chamber by a pressurization and depressurization apparatus and/or a vacuum generator to generate a wavy airflow, which is a fluctuation from a high pressure to vacuum, performing intermittent fluctuation within a range from a maximum value of 50 atm to a minimum value of 10⁻⁵ atm, and removing the substance to be cleaned that is attached to each of the circuit substrates from each of the circuit substrates and the liquid material more effectively via frictional scrubbing of the liquid material in contact with the substance to be cleaned due to a fluctuation change in the liquid material caused by a fluctuation change of the gas.

10. The process for flip chip packaging according to claim 9, wherein the soldering flux is a liquid soldering flux with the viscosity ranging from 1 cps to 1,000 Pa·s.

11. The process for flip chip packaging according to claim 9, wherein the substance to be cleaned is the soldering flux, a soldering flux residue, grease, a photoresist, or a substance generated in the process.

12. The process for flip chip packaging according to claim 9, wherein the liquid material is an underfill, the underfill is capable of containing hard particles, the hard particles roll as the underfill fluctuates, and a frictional scrubbing effect is enhanced by means of the hard particles.

13. The process for flip chip packaging according to claim 12, wherein the underfill has a component of epoxy resin.

14. The process for flip chip packaging according to claim 9, wherein each of the aligned chips and each of the circuit substrates are conveyed by means of an automated conveying device.

15. The process for flip chip packaging according to claim 14, wherein the automated conveying device comprises at least one transfer vehicle and at least one magazine, each of the aligned chips and each of the circuit substrates are accommodated in the at least one magazine, and the at least one transfer vehicle conveys each of the aligned chips and each of the circuit substrates.

16. The process for flip chip packaging according to claim 15, wherein the transfer vehicle comprises an overhead hoist transport (OHT), an automated guided vehicle (AGV), an autonomous mobile robot (AMR), and a rail guided vehicle (RGV).

17. A process for flip chip packaging, comprising the following steps:
(a): preparing a plurality of chips, wherein each of the chips is provided with an active surface, and a plurality of conductive bumps are disposed on the active surface;
(b): preparing a plurality of circuit substrates, wherein each of the circuit substrates is provided with a bearing surface, and a solder pad corresponding to each of the conductive bumps is disposed on the bearing surface;
(c): coating a surface of each of the solder pads with a soldering flux, flipping and aligning each of the chips to ensure that the active surface of each of the chips is configured facing the bearing surface of each of the circuit substrates, conveying each of the aligned chips and each of the circuit substrates into a batch reflow oven, bonding each of the conductive bumps to each of the solder pads via the soldering flux, and performing a metal soldering operation to electrically and structurally connect each of the chips to each of the solder pads on each of the circuit substrates by means of each of the conductive bumps, thereby preparing a plurality of flip chip package structures;
(d): infilling a liquid material between each of the circuit substrates and each of the chips to cover a substance to be cleaned on each of the circuit substrates;
(e): placing each of the flip chip package structures containing the liquid material in a processing chamber, and heating the processing chamber to at least a predetermined temperature, wherein the predetermined temperature needs to match the viscosity of the liquid material and is between 25° C. and 200° C.; and
(f): performing intermittent pressurization and depressurization on gas in the processing chamber by a pressurization and depressurization apparatus to generate a wavy airflow, which is a fluctuation from high pressure to 1 atm, performing intermittent fluctuation within a range from a maximum value of 50 atm to a minimum value of 1 atm, and removing the substance to be cleaned that is attached to each of the circuit substrates from each of the circuit substrates and the liquid material more effectively via frictional scrubbing of the liquid material in contact with the substance to be cleaned due to a fluctuation change in the liquid material caused by a fluctuation change of the gas.

18. The process for flip chip packaging according to claim 17, wherein the soldering flux is a liquid soldering flux with the viscosity ranging from 1 cps to 1,000 Pa·s.

19. The process for flip chip packaging according to claim 17, wherein the substance to be cleaned is the soldering flux, a soldering flux residue, grease, a photoresist, or a substance generated in the process.

20. The process for flip chip packaging according to claim 17, wherein the liquid material is an underfill, the underfill is capable of containing hard particles, the hard particles roll as the underfill fluctuates, and a frictional scrubbing effect is enhanced by means of the hard particles.

21. The process for flip chip packaging according to claim 20, wherein the underfill has a component of epoxy resin.

22. The process for flip chip packaging according to claim 17, wherein each of the aligned chips and each of the circuit substrates are conveyed by means of an automated conveying device.

23. The process for flip chip packaging according to claim 22, wherein the automated conveying device comprises at least one transfer vehicle and at least one magazine, each of the aligned chips and each of the circuit substrates are accommodated in the at least one magazine, and the at least one transfer vehicle conveys each of the aligned chips and each of the circuit substrates.

24. The process for flip chip packaging according to claim 23, wherein the transfer vehicle comprises an overhead hoist transport (OHT), an automated guided vehicle (AGV), an autonomous mobile robot (AMR), and a rail guided vehicle (RGV).

25. A process for flip chip packaging, comprising the following steps:
(a): preparing a plurality of chips, wherein each of the chips is provided with an active surface, and a plurality of conductive bumps are disposed on the active surface;
(b): preparing a plurality of circuit substrates, wherein each of the circuit substrates is provided with a bearing surface, and a solder pad corresponding to each of the conductive bumps is disposed on the bearing surface;
(c): coating a surface of each of the solder pads with a soldering flux, flipping and aligning each of the chips to ensure that the active surface of each of the chips is configured facing the bearing surface of each of the circuit substrates, conveying each of the aligned chips and each of the circuit substrates into a batch reflow oven, bonding each of the conductive bumps to each of the solder pads via the soldering flux, and performing a metal soldering operation to electrically and structurally connect each of the chips to each of the solder pads on each of the circuit substrates by means of each of the conductive bumps, thereby preparing a plurality of flip chip package structures;
(d): infilling a liquid material between each of the circuit substrates and each of the chips to cover a substance to be cleaned on each of the circuit substrates;
(e): placing each of the flip chip package structures containing the liquid material in a processing chamber, and heating the processing chamber to at least a predetermined temperature, wherein the predetermined temperature needs to match the viscosity of the liquid material and is between 25° C. and 200° C.; and
(f): generating at least a predetermined gas pressure ranging from a maximum value of 50 atm to a minimum value of 1 atm in the processing chamber by a pressurization apparatus, dissolving the substance to be cleaned that is attached to each of the circuit substrates in the liquid material by using physical dissolution caused by contact between the infilled liquid material and the substance to be cleaned, and removing the substance to be cleaned that is attached to each of the circuit substrates from each of the circuit substrates and the liquid material more effectively by using a diffusion force generated by the predetermined temperature and a concentration gradient after dissolution.

26. The process for flip chip packaging according to claim 25, wherein the soldering flux is a liquid soldering flux with the viscosity ranging from 1 cps to 1,000 Pa·s.

27. The process for flip chip packaging according to claim 25, wherein the substance to be cleaned is the soldering flux, a soldering flux residue, grease, a photoresist, or a substance generated in the process.

28. The process for flip chip packaging according to claim 25, wherein the liquid material is an underfill, the underfill is capable of containing hard particles, the hard particles roll as the underfill fluctuates, and a frictional scrubbing effect is enhanced by means of the hard particles.

29. The process for flip chip packaging according to claim 28, wherein the underfill has a component of epoxy resin.

30. The process for flip chip packaging according to claim 25, wherein each of the aligned chips and each of the circuit substrates are conveyed by means of an automated conveying device.

31. The process for flip chip packaging according to claim 30, wherein the automated conveying device comprises at least one transfer vehicle and at least one magazine, each of the aligned chips and each of the circuit substrates are accommodated in the at least one magazine, and the at least one transfer vehicle conveys each of the aligned chips and each of the circuit substrates.

32. The process for flip chip packaging according to claim 31, wherein the transfer vehicle comprises an overhead hoist transport (OHT), an automated guided vehicle (AGV), an autonomous mobile robot (AMR), and a rail guided vehicle (RGV).
